(19) United States
(12) Patent Application Publication
(10) Pub. No.: US 2026/0056255 A1
(43) Pub. Date: Feb. 26, 2026

(54) FAULT DETECTION AND PROTECTION FOR COLLECTION SYSTEMS OF POWER MACHINES

(71) Applicant: Doosan Bobcat North America, Inc., West Fargo, ND (US)

(72) Inventor: Matt Keller, Bismarck, ND (US)

(21) Appl. No.: 19/281,332

(22) Filed: Jul. 25, 2025

Related U.S. Application Data
(60) Provisional application No. 63/677,442, filed on Jul. 31, 2024.

(51) Int. Cl. G01R 31/34; A01D 43/077; A01D 69/02; A01D 101/00; B60L 1/00

(52) U.S. Cl. CPC G01R 31/343; A01D 43/077; A01D 69/02; B60L 1/003; A01D 2101/00; B60L 2200/40; B60L 2250/16

(57) ABSTRACT

Methods and systems of controlling a power machine. The power machine may be controlled based on a fault condition determined responsive to detecting an electric current drop for an electric actuator of the power machine, which may result from a blockage in a discharge chute of the power machine.

### CROSS-REFERENCE TO RELATED APPLICATIONS

This application claims the benefit of U.S. provisional application No. 63/677,442, filed 31 Jul. 2024, which is hereby incorporated by reference in its entirety as though fully set forth herein.

### BACKGROUND

This disclosure is directed toward power machines. More particularly, this disclosure is related to power machines for mowing operations, including zero-turn mowers (i.e., mowers that can turn with a zero-turn radius). Power machines, for the purposes of this disclosure, include any type of machine that generates power to accomplish a particular task or a variety of tasks. One type of power machine is a work vehicle. Work vehicles are generally self-propelled vehicles that have a work device that can be operated to perform a work function. For example, mowers can include a mower deck with one or more rotatable blades that can be operated to cut grass, brush, or other material as the travels over terrain. Other work vehicles include loaders (including mini-loaders), excavators, utility vehicles, tractors (including compact tractors), and trenchers, to name a few examples.

The discussion above is merely provided for general background information and is not intended to be used as an aid in determining the scope of the claimed subject matter.

### SUMMARY

Some examples described herein relate to detecting a fault condition for a power machine and controlling the power machine responsive to the fault condition, and, more particularly, to controlling a power machine based on a fault condition, where the fault condition may be determined responsive to detecting an electric current drop for an electric actuator of the power machine.

As described in greater detail herein, the technology disclosed herein may monitor electric current data for an electric motor included in a collection system of a power machine (e.g., a mower). In some instances, the technology disclosed herein may determine and monitor electric current trends for the electric motor. Based on the monitored electric current (or electric current trends thereof), the technology disclosed herein may detect (or predict) a fault condition for the mower, including, e.g., a fault condition for the collection system of the mower. The technology disclosed herein may utilized one or more electric current thresholds, one or more electric current ranges (or windows), or a combination thereof, to detect an electric current drop (or reduction), which may be indicative of a fault condition (e.g., a blockage in a discharge chute of the collection system). When a fault condition is detected, the technology disclosed herein may control the mower (e.g., provide an alert to an operator of the mower, control operating parameters of the mower, etc.).

Some examples provide a method of controlling a power machine. The method may include monitoring, with an electronic processor, electric current for an electric motor of a collection system of the power machine; determining, with the electronic processor, a fault condition for the collection system responsive to detecting that the electric current is below a predetermined electric current threshold; and controlling, with the electronic processor, the power machine based on the fault condition.

In some examples, a system of controlling a power machine. The system may include one or more electronic processors. The one or more electronic processors may be configured to: monitor an electric current trend for an electric motor of a collection system of the power machine; detect a deviation of a present electric current of the electric motor from the electric current trend; when the deviation of the present electric current is a reduced electric current value relative to the electric current trend, determine a first fault condition for the collection system of the power machine; when the deviation of the present electric current is an increased electric current value relative to the electric current trend, determine a second fault condition for the power machine; and control the power machine based on the first or second fault condition.

Some examples provide a mower. The mower may include: a frame; a power source; a cutting assembly coupled to the frame and configured to be powered by the power source for cutting operations; one or more drive motors coupled to the frame and configured to be powered by the power source to move the mower over terrain during cutting operations. The mower may include a collection system coupled to the cutting assembly. The collection system may include a discharge chute coupled to the cutting assembly. The collection system may include an electric motor coupled to an impeller and configured to drive the impeller to control airflow within the discharge chute. The mower may include an electronic controller in communication with the one or more drive motors and the electric motor. The electronic controller may be configured to: monitor an electric current trend for the electric motor; detect a deviation of a present electric current of the electric motor from the electric current trend, where the deviation of the present electric current is a reduced electric current value relative to the electric current trend; determine, based on the deviation, a fault condition for the collection system; and control the mower based on the fault condition.

Some examples provide a mower. The mower may include: a frame; a power source; and a deck support assembly coupled to the frame and configured to be powered by the power source. The deck support assembly may include: a deck including a cutting blade configured to perform a cutting operation; and a first electric motor coupled to the cutting blade and configured to drive rotation of the cutting blade to perform the cutting operation. The mower may include a collection system coupled to the deck support assembly. The collection system may include: a discharge chute coupled to the frame; and a second electric motor coupled to an impeller and configured to drive the impeller to control airflow within the discharge chute. The mower may include an electronic controller in communication with the first electric motor and the second electric motor. The electronic controller may be configured to: control the first electric motor to drive rotation of the cutting blade to perform the cutting operation; and control the second electric motor to drive the impeller to control airflow within the discharge chute.

This Summary and the Abstract are provided to introduce a selection of concepts in a simplified form that are further described below in the Detailed Description. This Summary and the Abstract are not intended to identify key features or essential features of the claimed subject matter, nor are they intended to be used as an aid in determining the scope of the claimed subject matter.

### DRAWINGS

FIG. 1 is a block diagram illustrating functional systems of a representative power machine on which embodiments of the present disclosure can be advantageously practiced.

FIG. 2 is a perspective view showing generally a front of a power machine in the form of a zero-turn mower on which embodiments disclosed in this specification can be advantageously practiced.

FIG. 3 is a block diagram illustrating components of a hydraulic power system of a loader such as the mower of FIG. 2.

FIG. 4 schematically illustrates a system for controlling a power machine according to some embodiments.

FIG. 5 illustrates a collection system according to some configurations.

FIG. 6 schematically illustrates a controller of the power machine according to some embodiments.

FIG. 7 schematically illustrates an example arrangement of a control system including multiple controllers according to some configurations.

FIG. 8 schematically illustrates an example diagram of a shared controller configured to control multiple components of a power machine according to some configurations.

FIG. 9 is a flowchart illustrating a method of controlling a power machine using the system of FIG. 4 according to some embodiments.

FIG. 10 is a graph illustrating electric current data of an electric motor during a fault condition where a discharge chute is blocked according to some configurations.

FIG. 11 is a graph illustrating voltage data of an electric motor during a fault condition where a discharge chute is blocked according to some configurations.

FIG. 12 is a graph illustrating power data of an electric motor during a fault condition where a discharge chute is blocked according to some configurations.

### DESCRIPTION

The concepts disclosed in this discussion are described and illustrated by referring to exemplary embodiments. These concepts, however, are not limited in their application to the details of construction and the arrangement of components in the illustrative embodiments and are capable of being practiced or being carried out in various other ways. The terminology in this document is used for the purpose of description and should not be regarded as limiting. Words such as “including,” “comprising,” and “having” and variations thereof as used herein are meant to encompass the items listed thereafter, equivalents thereof, as well as additional items. In addition, any feature disclosed with respect to one embodiment may be included in another embodiment, and vice-versa.

The technology disclosed herein relates to fault detection and prevention for power machines, and, in particular, for mower collection systems. As described in greater detail herein, a mower collection system may include an electrically powered blower (e.g., an electric motor coupled to an impeller) attached to a discharge chute of the mower deck. The technology disclosed herein may monitor electric current data for the electric motor. In some instances, the technology disclosed herein may determine and monitor electric current trends for the electric motor. Based on the monitored electric current (or electric current trends thereof), the technology disclosed herein may detect (or predict) a fault condition for the mower, including, e.g., a fault condition for the collection system of the mower. The technology disclosed herein may utilized one or more electric current thresholds, one or more electric current ranges (or windows), or a combination thereof, to detect an electric current drop (or reduction), which may be indicative of a fault condition (e.g., a blockage in a discharge chute of the collection system, a full collection receptacle or bag downstream from the electric motor, etc.). For instance, when an impeller coupled to the electric motor stalls (due to a blockage within the discharge chute) too much pressure may be present in the system (e.g., in the discharge chute) and the air around the impeller may become turbulent, causing lower air resistance against rotation of the impeller, which may result in an even lower electric current than just moving air through the chute. Accordingly, as a result, the electric motor may draw less electric current (as opposed to when air around the impeller is laminar). In particular, an impeller may enter a fluid stall when the air within a housing of the impeller is turbulent, which may lead to a reduced electric current (e.g., an electric current below a threshold or range). The impeller may enter a physical stall when the impeller itself is blocked or impeded, which may lead to an increased electric current (e.g., an electric current above a threshold or range). Therefore, when the electric motor experiences an electric current drop, such an electric current drop may indicate a fault condition for the collection system of the mower. As described in greater detail herein, when a fault condition is detected, the technology disclosed herein may control the mower based on the fault condition (e.g., provide an alert to an operator of the mower, control operating parameters of the mower, etc.).

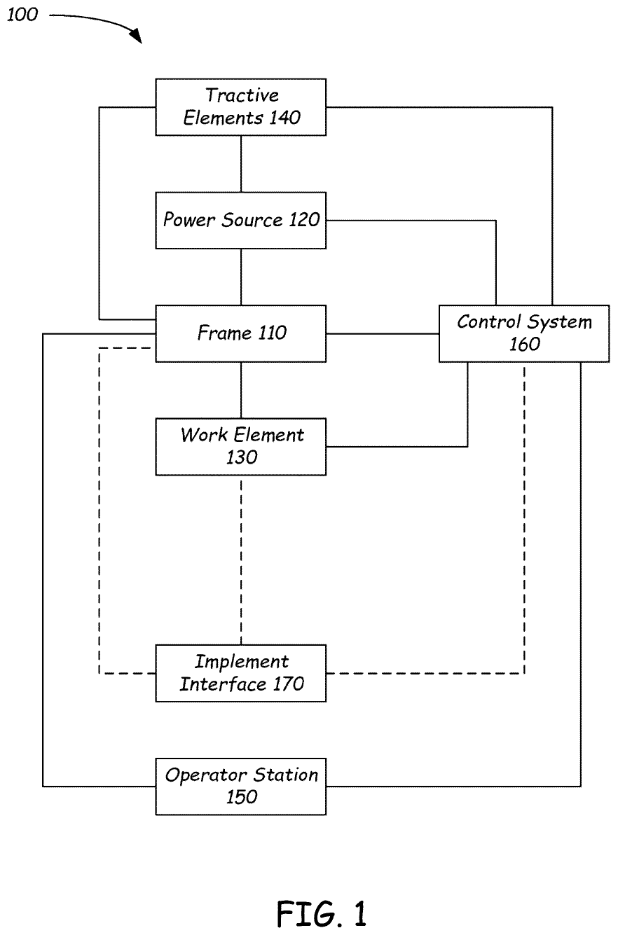

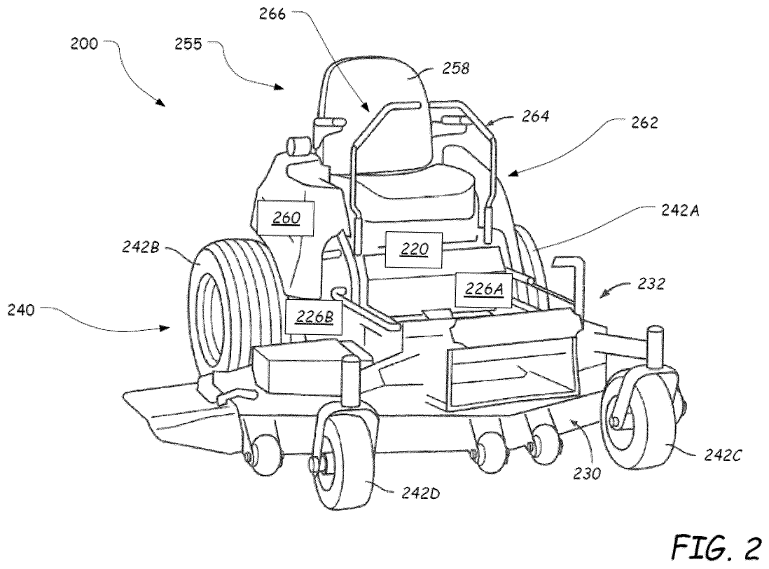

Embodiments described herein relate to controlling a power machine for determining fault conditions responsive to detecting an electric current drop (or reduction) while performing a mowing operation. These concepts can be practiced on various power machines, as will be described below. A representative power machine on which the embodiments can be practiced is illustrated in diagram form in FIG. 1 and one example of such a power machine is illustrated in FIG. 2 and described below before any embodiments are disclosed. For the sake of brevity, only one power machine is discussed. However, as mentioned above, the embodiments below can be practiced on any of a number of power machines, including power machines of different types from the representative power machine shown in FIG. 2. Power machines, for the purposes of this discussion, include a frame, at least one work element, and a power source that can provide power to the work element to accomplish a work task. One type of power machine is a self-propelled work vehicle. Self-propelled work vehicles are a class of power machines that include a frame, work element, and a power source that can provide power to the work element. At least one of the work elements is a motive system for moving the power machine under power. In some examples, a power machine can be a self-propelled mower, including a mower with a work element configured as a mower deck with one or more rotating blades, and additional work elements configured as separately controllable right-and left-side drive elements to allow skid-steer operation.

Although examples herein focus particularly power machines for mowing operations (e.g., a mower), implementations of the disclosed technology can be practiced on a variety of power machines with a variety of ground-engaging elements. In this regard, FIG. 1 is a block diagram that illustrates the basic systems of a power machine 100, which can be any of a number of different types of power machines and upon which the embodiments discussed below can be advantageously incorporated. The block diagram of FIG. 1 identifies various systems on power machine 100 and the relationship between various components and systems. In particular, the power machine 100 has a frame 110, a power source 120, a workgroup work element 130 and tractive work elements 140. The workgroup work element 130 can be operated to perform work tasks (e.g., mowing, digging, cutting, grading, etc.) and the tractive work elements 140 can be operated move the power machine over a support surface. In the illustrated example, the power machine 100 also includes an operator station 150 that provides an operating position for controlling the work elements of the power machine. In some examples, however, no operator station may be included.

A control system 160 is provided to interact with other systems of the power machine 100 to perform various tasks, including in response to control signals provided by an operator. For example, the control system 160 can be an integrated or distributed architecture of one or more controllers (e.g., one or more processor devices and one or more memories) that are collectively configured to receive operator input or other input signals (e.g., sensor data) and to output commands accordingly for power machine operations (e.g., workgroup operations, tractive operations, etc.).

Some power machines have work elements that can perform a dedicated task. For example, some power machines include a mower deck that can be attached to a main frame of the work vehicles in various ways (e.g., with a fixed mount, as an implement attached to a lift arm, etc.). Cutting elements of the mower deck can be controlled as needed. For example, the control system 160 can control the speed of one or more rotating blades, or a position of the mower deck relative to the frame, or the mower deck can be otherwise manipulated to perform mowing or other tasks.

Some power machines can include other dedicated work elements, including cutting or drilling implements, buckets, grading blades, and others as variously known in the art. In some cases, work elements can be interchanged on a particular power machine (e.g., as attachable implements that can be supported by a lift arm, or otherwise). In this regard, for example, the power machine 100 as illustrated includes an implement interface 170, which provides a connection between the frame 110 or the work element 130 and an attachable implement. In some cases, the implement interface 170 can be a direct connection to secure an implement directly to the frame 110 or to the work element 130 (e.g., can be a pinned connection directly to a lift arm). In some cases, the implement interface 170 can include a linkage or other support structure, or can be formed as an implement carrier (e.g., which may be configured to secure and support various implements, and may itself be controllably movable relative to the frame 110 or the work element 130). In some examples, the implement interface 170 can be a pinned or other connection that secures a mower deck to a movable support structure, so that the mower deck can be supported at selected heights relative to the frame 110 (and the ground).

In some example, the frame 110 can be rigid (e.g., formed from a single member, a weldment, or other unified structure). In some examples, at least one portion of the frame 110 may be movable relative to another. For example, excavators can have an upper frame portion that rotates with respect to a lower frame portion, and some power machines can include articulated frames that are pivotable about one or more vertical (or other) axes. Articulated frames, for example, can be used to implement steering operations, provide improved following of terrain, or otherwise.

The frame 110 supports the power source 120, which can provide power to the work element 130 or the tractive elements 140. In some cases, the power source 120 can provide power for use by an implement attached at the implement interface 170. In some examples, power from the power source 120 can be provided directly to the work element 130, the tractive elements 140, or implement interfaces 170 (e.g., via direct mechanical or electrical connection). In some examples, power from the power source can be provided indirectly to the work element 130, the tractive elements 140, or the implement interfaces 170 (e.g., may be transferred via hydraulic operations, or a combination of electrical and hydraulic operations). In some examples, the control system 160 can control routing of power from the power source 120 to other systems (e.g., via a system of electronic, hydraulic, electro-hydraulic, or other control devices, including as generally known in the art).

In some examples, the power source 120 can include an engine (e.g., an internal combustion engine). In some examples, the power source 120 can include an electrical power source (e.g., a battery, a capacitor, a fuel cell, etc.). In some examples, hybrid power sources can be provided (e.g., with a combination of an engine and an electrical power source). In some examples, a power conversion system can be provided to convert power from the power source 120 into other forms useable by the work element 130, the tractive elements 140, or an implement at the implement interface 170. For example, a hydraulic system can be used to convert rotational output from the power source 120 into hydraulic power (e.g., to power hydrostatic or other operations). Similarly, an electrical system can be used to convert electrical output from the power source 120 into non-electrical power (e.g., rotational mechanical power, or hydraulic power via a coupled hydraulic system).

For simplicity of presentation, FIG. 1 shows simple the work element 130, but various examples can include various numbers of work elements. In some examples, as also discussed above, work elements can include mower decks or other similar equipment. In some examples, work elements can include lift arm assemblies or other similar systems. The tractive elements 140 are a special case of work elements and may be provided in various number and configuration. In some examples, tractive elements can be arranged and controllable for independent operation and can be steerable in some cases. In some examples, one or more tractive elements on a first side of the power machine 100 may be separately controllable from one or more tractive elements on a second side of the power machine 100 (e.g., controllable for rotation in opposite directions for “skid steer” operation). Tractive elements can be, for example, wheels attached to an axle, track assemblies, or other assemblies of known configurations to convey tractive power from the frame 110 to a supporting surface.

In some examples, the tractive elements 140 can be rigidly mounted to the frame 110 so as to be limited to rotation about one or more corresponding axles. In some examples, the tractive elements 140 can be pivotally mounted to the frame 110. In some power machines, including zero-radius turn mowers, one or more caster wheels or similar devices can be used in combination with rigidly mounted tractive elements, with the rigidly mounted tractive elements provide tractive power and allowing the power machine to be steered via implementation of different ground-engaging speeds at tractive elements on opposing sides of the power machine. Such an arrangement is referred to herein as a zero-radius turn configuration and can in particular be implemented on mowers, as further discussed below.

In some power machines, the operator station 150 is defined by an enclosed or partially enclosed cab. In some examples, the operation station 150 can include a standing or other platform (e.g., without overhead enclosure). In some examples, the operator station 150 can be a remote station (e.g., as provided by a remote control device not attached to the frame 110). In some examples, the operator station 150 can be supported by the frame 110 by accessible by operators that are not (e.g., by an operator walking behind the power machine 100).

FIG. 2 illustrates a mower 200, which is one particular example of the power machine 100 FIG. 1. Correspondingly, features of the mower 200 described include reference numbers that are generally similar to those used in FIG. 1 and discussion above of similarly named or numbered components also applies to the mower 200, unless otherwise indicated. For example, the mower 200 includes a frame 210, just as power machine 100 has the frame 110.

The mower 200 is shown as a zero-radius turn riding mower, but it could also be a differently configured riding mower, or a walk-behind or push-type mower. In particular, a zero-radius turn mower can be capable of executing a turn with a turn radius of zero (i.e., the mower can be capable of rotating about a vertical axis through the machine to execute up to a 360 degree turn). However, some turns may be performed with a non-zero turn radius and some similarly configured mowers (or other power machines) may not be capable of fully zero-radius turns.

In the illustrated configuration of the mower 200, the frame 210 supports a power system 220 that can generate or otherwise provide power for operating various functions on the power machine. The frame 210 also supports a work element in the form of a mower deck 230 that is powered by the power system 220 and that can perform various work tasks (e.g., cutting at different blade speeds or deck heights). The frame 210 also supports a tractive system 240, which is also powered by a power system 220 and can propel the power machine over a support surface. In particular, in the illustrated example, the tractive system 240 includes powered wheels 242A, 242B, as further discussed below, as well as un-powered casters 242C, 242D, which are capable of rotation about a vertical or substantially vertical axis to assist with steering of the mower. The casters 242C, 242D can rotate in response to uneven application of power to the wheels 242A, 242B (in terms of magnitude or direction) or other factors, to allow the mower to turn without skidding without the casters 242C, 242D necessarily being actively controlled.

A deck support assembly 232 supports the deck 230 relative to the frame 210 and can be configured for selective adjustment to provide different cutting heights, angles, etc. for the deck 230, as well as for selective removal of the deck 230 or installation of additional or alternative work elements (e.g., other mower decks, ducts, and other material handling devices for cut plant material, etc.). The deck 230 can include one or more rotatable blades (not shown), which can be controlled (e.g., collectively or individually) to cut grass or other material, and which can be powered by hydraulic, electronic, or mechanical connections to the power system 220.

As a riding lawn mower, the mower 200 includes an operator station 255 supported on the frame 210, from which an operator can manipulate various control devices to cause the mower 200 to perform various work functions. In the illustrated example, in particular, the operator station 250 includes an operator seat 258, as well as the various operation input devices 262 in communication with a control system 260 (e.g., a hydraulic control system, or an electronic control system including an electronic hub controller and other distributed controllers that are electronically in communication with the hub controller). The input devices 262 generally allow an operator to control tractive and workgroup operations, so that the mower 200 can be directed to move over terrain and selectively cut grass or other plants along the terrain (or otherwise executed desired work operations).

In some case, the input devices 262 can allow for tractive control of the mower 200. For example, the input devices 262 can include left-and right-side control levers 264, 266 (e.g., “lap bars”, as shown) that can be independently moved by an operator to direct, respectively, rotation of left-and right-side drive actuators 226A, 226B for independent commanded rotation of left-and right-side tractive elements (e.g., the wheels 242A, 242B, as shown). In some cases, the levers 264, 266 can directly control delivery of hydraulic or other power. In some cases, the levers 264, 266 can indirectly control power delivery, including by adjusting a pilot flow for a powered hydraulic system of the mower 200 or by providing electronic signals that direct control of hydraulic, electronic, or other power delivery systems by way of one or more intervening hydraulic or electronic controllers included in the control system 260.

In some examples, other configurations are possible for operator input devices, including configurations with different types of control levers that an operator can manipulate to control various machine functions. In some configurations, the operator input devices 262 can include a joystick (e.g., only a single electronic joystick for tractive operations), a steering wheel, buttons, switches, levers, sliders, pedals and the like, which can be stand-alone devices (e.g., hand operated levers or foot pedals), or can be incorporated into hand grips or display panels. In some cases, one or more of the input devices can include programmable input devices.

As generally noted above, actuation of operator input devices can generate signals in the form of electrical signals, hydraulic signals, mechanical signals, or a combination thereof. Signals generated in response to operator input devices are provided to various components on the power machine for controlling various functions on the power machine. Functions that can be controlled via operator input devices on the mower 200 can include operational functions of the tractive system 240, the mower deck 230, other implements (not shown) including various other attachments (not shown), or a combination thereof.

In some cases, the control system 260 can be configured to operate without input from operator input devices 262 for one or more operations. For example, the control system 260 can be configured for automatic or autonomous control of certain operations of the mower 200 or can include wireless communication capabilities so as to receive control commands or other relevant data from remotely located (i.e., not mechanically tethered) and other systems, as described in greater detail below. Correspondingly, unless otherwise indicated, discussion herein of operator commands or inputs can indicate commands or inputs from an automatic or autonomous system in some cases.

Mowers can sometimes include other human-machine interfaces, including display devices (not shown) that are provided in the operator station 255 to give indications of information relatable to the operation of the power machines in a form that can be sensed by an operator (e.g., audial or visual indications). Audial indications can include buzzers, bells, and the like or verbal communication. Visual indications can include graphs, lights, displays of color(s), icons, gauges, alphanumeric characters, and the like. Displays can be dedicated to providing dedicated indications, including warning lights or gauges, or can dynamically provide information (e.g., via programmable display devices such as monitors of various sizes and capabilities). Thus, display devices can generally provide diagnostic information, troubleshooting information, instructional information, and various other types of information that assists an operator with operation of the power machine or an implement coupled to the power machine.

The power system 220 generally includes one or more power sources that can generate or otherwise provide power for operating various machine functions. For example, the power system 220 can include an internal combustion engine, an electric generator, rechargeable or replaceable batteries, capacitors, fuel cells, or various other power sources or combinations thereof. The power source(s) of the power system 220 can be operatively coupled to one or more actuators that can thus be powered for tractive, workgroup, or other operations.

In particular, in the illustrated example, the power source(s) of the power system 220 can be operatively coupled to tractive actuators 226A, 226B that can power rotational movement of the wheels 242A, 242B, respectively. In a hydraulically powered example, the tractive actuators 226A, 226B can be hydrostatic motors that are hydraulically coupled to corresponding hydrostatic drive pumps (not shown) that are powered by the power source(s) of the power system 220. In an electrically powered example, the tractive actuators 226A, 226B can be electric motors that are electrically coupled to corresponding motor drives (not shown) that are powered by the power source(s) of the power system 220. The control system 260 may correspondingly be configured to control operation of the tractive actuators 226A, 226B based on operator input (e.g., via control of corresponding hydrostatic drive pumps or motor drives, or as otherwise generally known in the art). In some examples, additional actuators can be included and can be similarly controllable (e.g., an implement pump or motor to power operation of the mower deck 230, etc.).

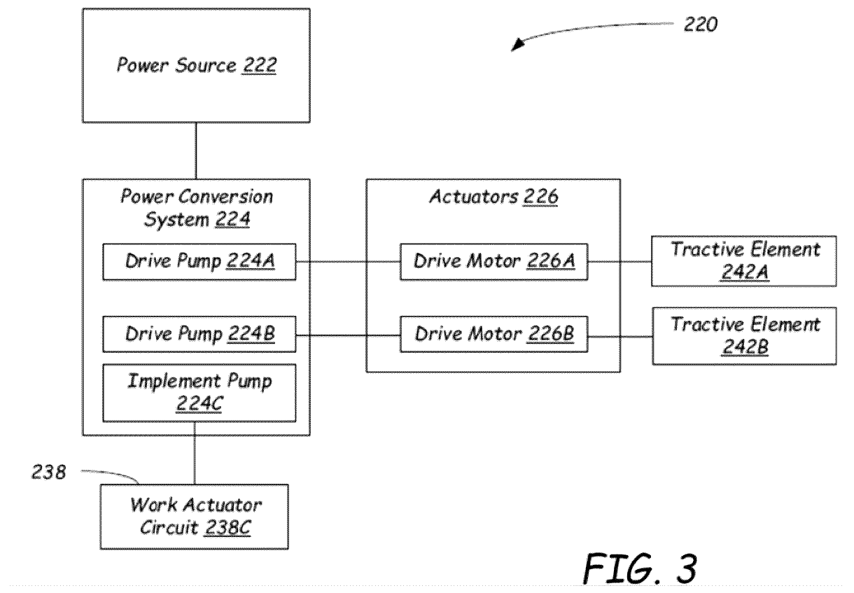

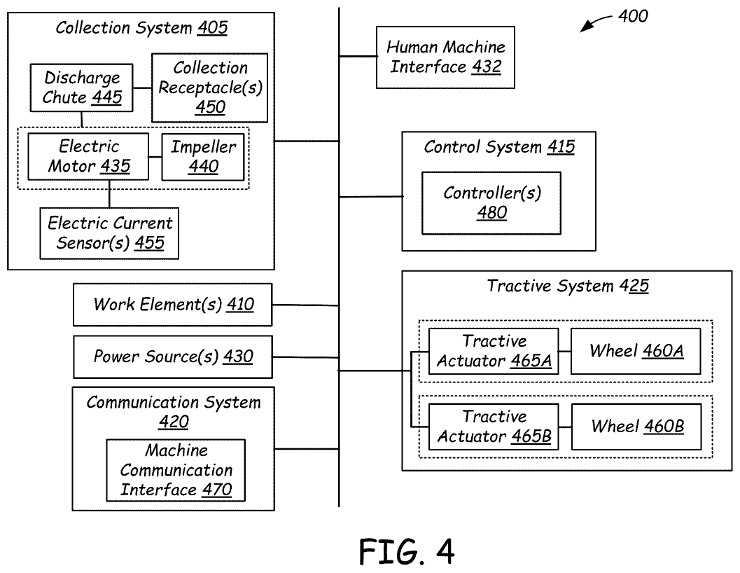

FIG. 3 illustrates an example of power system 220 in more detail for a hydraulically powered system. Broadly speaking, power system 220 includes one or more power sources 222 that can generate and/or store power for operating various machine functions. On mower 200, the power system 220 includes an internal combustion engine. Other power machines can include electric generators, rechargeable or replaceable batteries, various other power sources or any combination of power sources that can provide power for given power machine components. The power system 220 also includes a power conversion system 224, which is operably coupled to the power source 222. Power conversion system 224 is, in turn, coupled to one or more actuators 226, which can perform a function on the power machine. Power conversion systems in various power machines can include various components, including mechanical transmissions, hydraulic systems, and the like. In a hydraulically powered example, the power conversion system 224 of power machine 200 can include hydrostatic drive pumps 224A, 224B, which provide a power signal to drive motors 226A, 226B, respectively. The drive motors 226A, 226B in turn are each operably coupled to a respective tractive element 242A, 242B (e.g., the wheels 242A, 242B as shown in FIG. 2). The hydrostatic drive pumps 224A, 224B can be mechanically, hydraulically, or electrically coupled to operator input devices (or otherwise in communication with the control system 260) to receive actuation signals for controlling the drive pump. The power conversion system also includes an implement pump 224C, which can be driven by the power source 222 to provide pressurized hydraulic fluid to a work actuator circuit 238 for operation of a work actuator 239 (e.g., one or more motors for rotation of the blades of the deck 230). The work actuator circuit 238 can include valves and other devices to selectively provide pressurized hydraulic fluid to the various work actuators represented by block 239 in FIG. 4. In addition, the work actuator circuit 238 can be configured to provide pressurized hydraulic fluid to work actuators on an attached implement.

As also noted above, in some cases actuators of a power machine can be electrically powered. Correspondingly, in some cases, the power conversion system 224 may include electronic or other devices configured for transmission of electric current to, and general control of, one or more electric motors included in the actuators 226 (e.g., left-and right-side drive motors) and one or more electric motors of non-tractive work elements (e.g., electronic motors included on the deck 230 to power rotation of cutting blades).

The description of power machine 100 and mower 200 above is provided for illustrative purposes, to provide illustrative environments on which the embodiments discussed below can be practiced. While the embodiments discussed can be practiced on a power machine such as is generally described by the power machine 100 shown in the block diagram of FIG. 1 and more particularly on a mower such as zero-turn mower 200, unless otherwise noted or recited, the concepts discussed below are not intended to be limited in their application to the environments specifically described above.

FIG. 4 schematically illustrates an example power machine 400 according to some embodiments. In some instances, the power machine 400 may be a mower, such as, e.g., the mower 200 of FIG. 2. In the example illustrated in FIG. 4, the power machine 400 includes a collection system 505, one or more work elements 410 (for example, the work elements 130, as described above), a control system 415 (for example, the control system 160, as described above), a communication system 420, a tractive system 425, a power source 430, and a human-machine interface 432. The collection system 405, the work element(s) 410, the control system 415, the communication system 420, the tractive system 425, the power source 430, and the human-machine interface 432 communicate over one or more communication lines or buses. The power machine 400 may include additional, fewer, or different components than those illustrated in FIG. 4 in various configurations and may perform additional functionality than the functionality described herein. For example, the power machine 400 may include additional, similar, or different components, systems, and functionality as described above with respect to the power machine 100 of FIG. 1 and the mower 200 of FIG. 2. In some cases, as also discussed below, the work elements 410 can include a mower deck or other mowing implements.

The collection system 405 may be configured to facilitate collection or removal of material resulting from operation of the power machine 400. As one example, where the work elements 410 of the power machine 400 includes a mower deck, operation of the mower deck, including, e.g., one or more cutting implements, may produce yard clippings or other yard waste or material (e.g., leaf or grass clippings). Following this example, the collection system 405 may facilitate the collection or removal of the grass clippings produced as a result of performing one or more mowing or cutting operations with, e.g., the work element(s) 410.

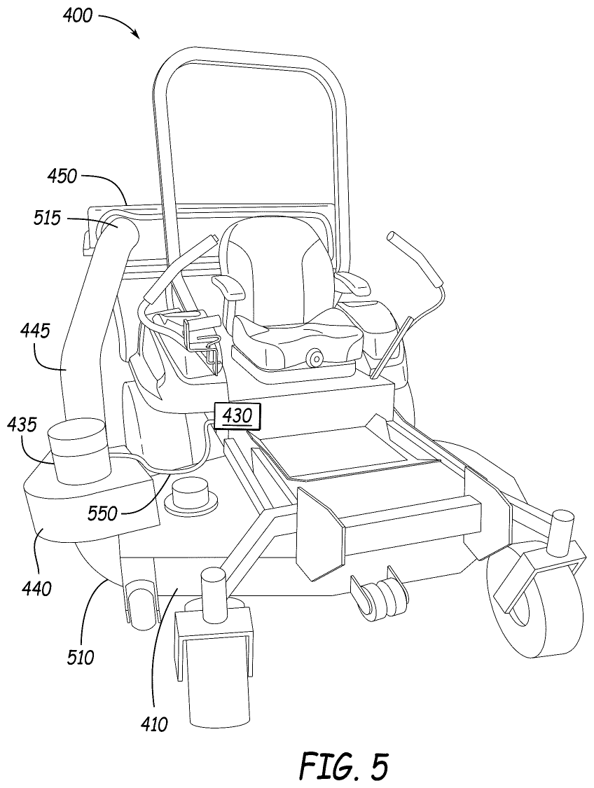

As illustrated in FIG. 4, the collection system 405 may include an electric motor 435, an impeller 440, a discharge chute 445, one or more collection receptacle 450, and one or more electric current sensor(s) 455. The collection system 405 may include additional, fewer, or different components than those illustrated in FIG. 4 in various configurations and may perform additional functionality than the functionality described herein. For example, the collection system 405 may include multiple collection receptacles 450, multiple discharge chutes 445, multiple electric motors 435, multiple impellers 440, or multiple electric current sensors 455. The collection system 405 is described herein with reference to FIG. 5. FIG. 5 illustrates the collection system 405 on a mower (e.g., the power machine 400) according to some configurations.

As illustrated in FIGS. 4 and 5, the collection system 405 may include the discharge chute 445. In some configurations, the discharge chute 445 may be coupled to the power machine 400 (e.g., a frame of the power machine 400). In some examples, as illustrated in FIG. 5, the discharge chute 445 may be coupled between a mower deck (e.g., the work element 410) and the collection receptacle(s) 450. As illustrated in FIG. 5, a first end 510 the discharge chute 445 may be coupled to the mower deck and a second end 515 of the discharge chute 445 may be coupled to the collection receptacle(s) 450. In some instances, the first end 510 may be referred to herein as an ingress of the discharge chute 445 and the second end 515 may be referred to herein as an egress of the discharge chute 445. The discharge chute 445 may define (or otherwise provide) an enclosed channel or pathway between the mower deck and the collection receptacle(s) 450 such that yard waste may travel from an area below the mower deck to the collection receptacle(s). A flow of air within the discharge chute 445 may cause the yard waste to travel along the enclosed channel or pathway of the discharge chute 445 (e.g., from below the mower deck to the collection receptacle(s) 450).

The flow of air within the discharge chute 445 may result from rotation (or movement) of the impeller 440. The impeller 440 may be coupled to the electric motor 435 such that the electric motor 435 drives the impeller 440, and, thus, generates the flow of air within the discharge chute 445 (e.g., along the enclosed channel or pathway of the discharge chute 445). In some configurations, the electric motor 435 may be powered by a power system (e.g., the power conversion system 224 of FIG. 2 or the power source(s) 430 of FIG. 4). The electric motor 435 may receive electric current from the power system (e.g., the power source(s) 430) such that the electric motor 435 may power rotation of the impeller 440. For example, as illustrated in the example of FIG. 5, the electric motor 435 receive electric current via a wired connection (or cable) 550. In some configurations, the electric motor 435 may be controlled by the control system 415 (for example, via one or more control signals received from the control system 415).

The impeller 440 may be a rotating fan type wheel unit that may generate or control airflow within the discharge chute 445. In some instances, when driven by the electric motor 435, the impeller 440 may drive air and/or yard waste along the enclosed channel of the discharge chute 445. In some instances, the airflow within (or otherwise moving through) a housing of the impeller 440 (or along the discharge chute 445) may have a laminar flow. An airflow may be considered laminar when the air generally remains smooth or on regular paths. The airflow within a housing of the impeller 440 (or along the discharge chute 445) may be laminar under normal operating conditions (e.g., when the power machine 400 does not experience a fault condition, as described in greater detail herein). In other instances, the airflow within a housing of the impeller 440 (or along the discharge chute 445) may have a turbulent flow. An airflow may be considered turbulent when the air undergoes irregular fluctuations or paths (e.g., continuous changes in magnitude or direction). As described in greater detail herein, the airflow within a housing of the impeller 440 (or along the discharge chute 445) may be turbulent responsive to abnormal normal operating conditions (e.g., when the power machine 400 is experiencing a fault condition or a fault condition is imminent). As one example, the airflow within the housing of the impeller 440 may be turbulent when the impeller 440 is experiencing a fluid stall, which may result from, e.g., a blockage within the discharge chute 445.

The collection system 405 may include one or more electric current sensor(s) 455. As illustrated in the example of FIG. 4, the electric current sensor(s) 455 may be coupled to the electric motor 435. The electric current sensor(s) 455 may measure or determine an electric current being provided to (or by) a particular electric component, such as, e.g., the electric motor 435. Accordingly, in some configurations, the electric current sensor(s) 455 may detect electric current data for the electric motor 435.

The collection receptacle(s) 450 are configured to receive and store yard waste produced during operation of the power machine 400 (e.g., a cutting operation or a mowing operation). In some instances, the collection receptacle(s) 450 may be removably coupled to the power machine 400 such that, e.g., when the collection receptacle(s) 450 reach a maximum fill capacity (e.g., a maximum volume of yard waste that a respective collection receptacle may hold), an operator of the power machine 400 may remove the collection receptacle(s) 450 in order to empty the collected yard waste. In some instances, the collection receptacle(s) 450 may be emptied without removing the collection receptacle(s) 450 from the power machine 400.

As described above with respect to the work elements 130 of FIG. 1, the work element(s) 410 may be configured to perform a work task or operation, such as, for example, a mowing operation, a cutting operation, or another lawn maintenance task. As one example, the work element 410 is a mower deck (e.g., the mower deck 230 of FIG. 2) with one or more rotating blades that can be powered to perform a cutting operation (e.g., at different blade speeds or deck heights). The work element 410 may be attached or mounted to a main frame of the power machine 400 (e.g., the frame 110 of FIG. 1). For example, the work element 410 may be supported by a deck support assembly (e.g., the deck support assembly 232 of FIG. 2) relative to the main frame of the power machine 400. In some embodiments, the work element 410 is movable with respect to the frame when performing a work task (e.g., a mowing event). Via selective adjustment of the deck support assembly, for example, the work element 410 may be configured to function at different cutting heights, angles, and the like.

As described in greater detail below, the work element 410 may be controlled by the control system 415 (for example, via one or more control signals received from the control system 415). As one example, a rotational speed of the one or more rotating blades may be controlled based on a control signal received from the control system 415. As another example, a height of the mowing deck and, ultimately, of the rotating blades, may be controlled based on a control signal received from the control system 415. Accordingly, in some embodiments, the work element 410 is associated with an actuator (not illustrated), such as a linear actuator.

As illustrated in FIG. 4, the power machine 400 also includes the tractive system 425 (e.g., the tractive system 240 of FIG. 2), which is configured to propel the power machine 400 over terrain or, more generally, a support surface. As similarly described herein with respect to the powered wheels 242A and 242B of FIG. 2, the wheels 460A, 460B may be rotated by tractive actuators 465A, 465B, respectively.

The communication system 420 includes a machine communication interface 470, which allows the power machine 400 (e.g., one or more components thereof) to communicate with devices external to the power machine 400. As one example, the power machine 400 may communicate with a user device through the machine communication interface 470. A user device may include, e.g., a mobile communication device (e.g., a cellular phone), a laptop, a tablet, a desktop computer, a wearable computing device, etc. The machine communication interface 470 may include a port for receiving a wired connection to an external device (e.g., a universal serial bus (“USB”) cable and the like), a transceiver for establishing a wireless connection to an external device (e.g., over one or more communication networks, such as the Internet, local area network (“LAN”), a wide area network (“WAN”), and the like), or a combination thereof.

The human-machine interface 432 is configured to give indications of information relatable to the operation of the power machine 400 in a form that can be sensed by an operator (e.g., audial or visual indications). Audial indications can include buzzers, bells, and the like or verbal communication. Visual indications can include graphs, lights, displays of color(s), icons, gauges, alphanumeric characters, and the like. In some instances, the human-machine interface 432 may include a display device. A display device can be dedicated to providing dedicated indications, including warning lights or gauges, or can dynamically provide information (e.g., via programmable display devices such as monitors of various sizes and capabilities). Thus, display devices can generally provide diagnostic information, troubleshooting information, instructional information, and various other types of information that assists an operator with operation of the power machine or an implement coupled to the power machine. Alternatively, or in addition, in some instances, the human-machine interface 432 may include one or more indicator lights (e.g., LEDs).

The control system 415 (e.g., the control system 160 of FIG. 1) is configured to receive operator input or other input signals (e.g., sensor data, such as the speed data, the position data, the object data, or a combination thereof) and to output commands accordingly to control operation of the power machine 400. For example, the control system 415 can communicate with other systems of the power machine 400 to perform various work tasks, including to control tractive and implement actuators for travel and cutting operations over the course of a mowing event. In some embodiments, the control system 415 receives input from an operator input device, such as one of the operator input devices 262 of FIG. 2, including input as command signals provided by an operator of the power machine 400 via the operator input device. In response to receiving the input, the control system 415 may control the power machine 400 to perform a work task based at least in part on the input received from the operator input device.

Alternatively, or in addition, the control system 415 can be configured to detect a fault condition for the power machine 400, as described in greater detail herein. As one example, the control system 415 may detect a fault condition for the collection system 405. As one example, a fault condition may include a blockage within the discharge chute 445 of the collection system 405. As used herein, a blockage may refer to an obstruction or clog within the discharge chute 445 such that airflow within the discharge chute 445 is interrupted or prevented (e.g., corresponding to airflow within a housing of the impeller 440 is turbulent). As another example, a fault condition may include a maximum volume of yard waste collected within the collection receptacle(s) 450. In some configurations, the control system 415 may predict an imminent or impending fault condition for the power machine 400 (including, e.g., the collection system 405).

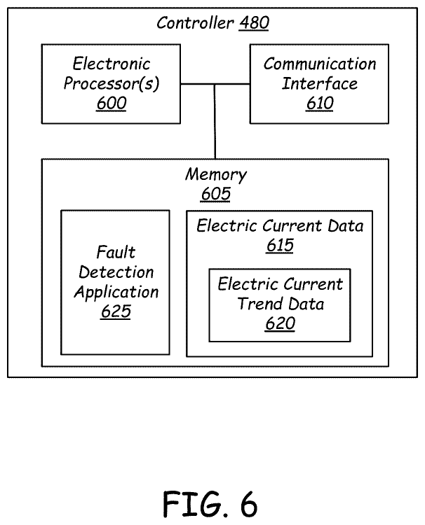

As illustrated in FIG. 4, the control system 415 includes one or more controllers 480. FIG. 6 illustrates an example controller 480 according to some embodiments. In the illustrated example of FIG. 6, the controller 480 includes an electronic processor 600 (for example, a microprocessor, an application-specific integrated circuit (“ASIC”), or another suitable electronic device), a memory 605 (for example, a non-transitory, computer-readable medium), and a communication interface 610. The electronic processor 600, the memory 605, and the communication interface 610 communicate over one or more communication lines or buses. It should be understood that the controller 480 may include additional components than those illustrated in FIG. 6 in various configurations and may perform additional functionality than the functionality described herein. For example, in some embodiments, the functionality described herein as being performed by the controller 480 may be distributed among other components or devices.

The communication interface 610 allows the controller 480 to communicate with devices external to the controller 480. For example, as illustrated in FIG. 4, the controller 480 may communicate with the collection system 505 (including, e.g., the electric current sensor(s) 455, the electric motor 435, etc.), the work element(s) 410, the tractive system 425, the communication system 420, the power source 430, the human-machine interface 432, or a combination thereof through the communication interface 610. The communication interface 610 may include a port for receiving a wired connection to an external device (for example, a USB cable and the like), a transceiver for establishing a wireless connection to an external device (for example, over one or more communication networks, such as the Internet, LAN, a WAN, and the like), or a combination thereof. In some embodiments, the controller 480 can be a dedicated or stand-alone controller. In some embodiments, the controller 480 can be part of a system of multiple distinct controllers (e.g., a hub controller, drive controller, workgroup controller, etc.) or can be formed by a system of multiple distinct controllers (e.g., also with hub, drive, and workgroup controllers, etc.).

The electronic processor 600 is configured to access and execute computer-readable instructions (“software”) stored in the memory 605. The software may include firmware, one or more applications, program data, filters, rules, one or more program modules, and other executable instructions. For example, the software may include instructions and associated data for performing a set of functions, including the methods described herein.

As one example, as illustrated in FIG. 6, the memory 605 may store electric current data 615. The electric current data 615 may be collected by the electric current sensor(s) 455. As such, the electric current data 615 may describe electric current of the electric motor 435. Alternatively, or in addition, the electric current data 615 may be for one or more additional components of the power machine 400. Accordingly, in some configurations, the controller 480 may receive the electric current data 615 from the electric current sensor(s) 455. As illustrated in FIG. 6, in some configurations, the electric current data 615 may include electric current trend data 620. The electric current trend data 620 may represent an average electric current value for a series of historical electric current values for the electric motor 435. For instance, the electric current trend data 620 may indicate a normal (or expected) electric current of the electric motor 435 during performance of a work task or operation with the power machine 400.

In some instances, the memory 605 may store a fault detection application 625 (referred to herein as “the application 625”). Alternatively, or in addition, in some embodiments, the application 625 may be stored remotely, such as, for example, in a memory of a user device or another remote device or database, such that the application 625 is accessible by the controller 480.

The application 625 is a software application executable by the electronic processor 600. As described in greater detail below, the electronic processor 600 may execute the application 625 to detect (or predict) a fault condition for the power machine 400 (or a component thereof). As described in greater detail herein, the application 625 (when executed by the electronic processor 600) may receive, from the electric current senor(s) 455, electric current data for the electric motor 345. The application 625 (when executed by the electronic processor 600) may monitor the electric current for the electric motor 345 (e.g., the electric current data 615), and, in some instances, determine and monitor electric current trends for the electric motor 345 (e.g., the electric current trend data 620). Based on the electric current data 615, the electric current trend data 620, or a combination thereof, the application 625 (when executed by the electronic processor 600) may detect (or predict) a fault condition for the power machine 400 (or a component thereof). In some configurations, the application 625 may detect (or predict) the fault condition using one or more predetermined electric current thresholds, one or more electric current ranges (or windows), or a combination thereof, as described in greater detail herein.

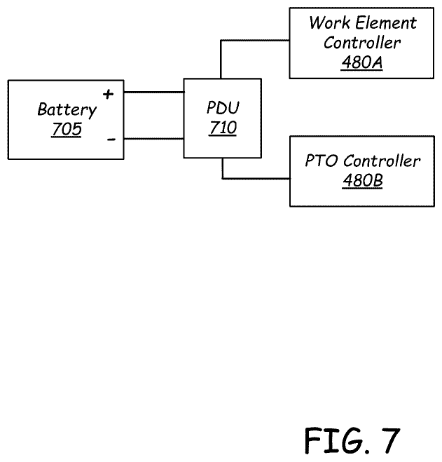

As noted herein, in some configurations, the control system 415 may include one or more controllers 480. As one example, FIG. 7 illustrates an example arrangement of the control system 415 where the control system 415 includes multiple controllers according to some configurations. As illustrated in FIG. 7, in some configurations, the control system 415 may include a work element controller 480A and a power take off (PTO) controller 480B. The work element controller 480A may be configured to control one or more of the work element(s) 410. For example, the work element controller 480A may control one or more mower decks (or cutting blades thereof) of the power machine 400 (e.g., the mower deck 230 of FIG. 2). The PTO controller 480B may be configured to control, e.g., one or more components of the collection system 505 (e.g., the electric motor 435). In the example of FIG. 7, the work element controller 480A and the PTO controller 480B may be powered by a battery 705 (e.g., the power source 430 of FIG. 4) via a power distribution unit (PDU) 710.

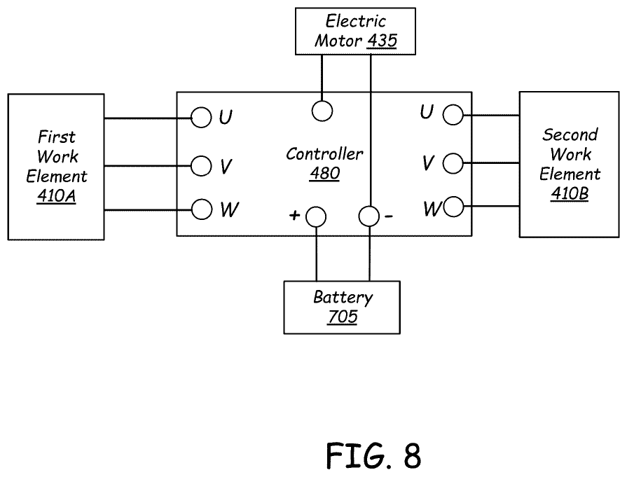

Alternatively, in some configurations, the functionality performed by the work element controller 480A and the functionality performed by the PTO controller 480B may be combined into a single controller (e.g., a shared controller), such as, e.g., the controller 480 of FIG. 6. In some configurations, the controller 480 may perform functionality of the work element controller 480A and the PTO controller 480B. For instance, the controller 480 may control operation of one or more mower decks of the power machine 400 and operation of the collection system 505 (e.g., the electric motor 435). As one example, FIG. 8 illustrates an example diagram of the controller 480 such that the controller 480 may perform the functionality of the work element controller 480A and the PTO controller 480B. For instance, the controller 480 may be coupled to the battery 705 (e.g., the power source 430 of FIG. 4), a first work element 410A (e.g., a first mower deck), a second work element 410B (e.g., a second mower deck), and an electric motor 435.

Accordingly, in some configurations, a shared controller may be utilized that controls the PTO and also controls the mower decks. In some cases, the PTO may be utilized to operate a blower, a dethatched, or other lawn maintenance equipment. For instance, the PTO may be utilized to operate the collection system 405 (e.g., the electric motor 435), as illustrated in FIG. 8. As one specific example, a DC output of the shared controller (e.g., the controller 480 of FIG. 8) may be used to supply DC power to the PTO (e.g., the electric motor 435 or another component of the collection system 405). In some configurations, a three-phase inverter may be integrated into the mower between the DC output of the controller 480 and the PTO. In such configurations, electric current from the DC output can be monitored (as described herein).

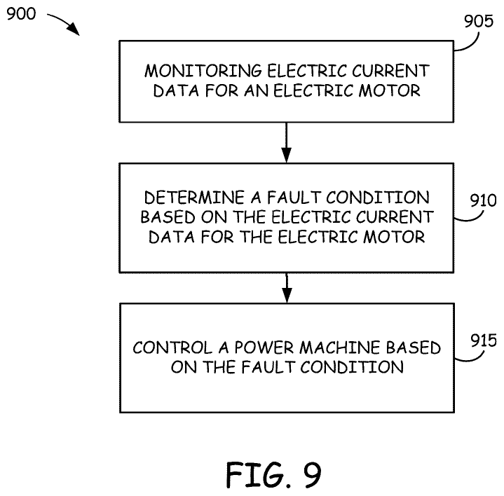

FIG. 9 is a flowchart illustrating a method 900 for controlling a power machine (for example, the power machine 400) according to some embodiments. In some embodiments, the method 900 can be performed by the control system 415 (e.g., the controller 480) and, in particular, the application 625 as executed by the electronic processor 600. However, as noted above, the functionality described with respect to the method 900 may be performed by other devices, or can be distributed among a plurality of devices or components.

As illustrated in FIG. 9, at block 905, the method 900 includes monitoring, with the electronic processor 600, the electric current data 615 for the electric motor 435. As described herein, the electronic processor 600 may receive the electric current data 615 from the electric current sensor(s) 455. The electronic processor 600 may receive the electric current data 615 in real time (or near real-time) such that the electric current data 615 is continuously updated. Alternatively, in some instances, the electronic processor 600 may receive the electric current data 615 periodically or intermittently (e.g., every five minutes). As noted herein, the electric current data 615 may include the electric current trend data 620. Accordingly, in some configurations, the electronic processor 600 may monitor electric current trend data 620 (e.g., as part of block 905).

The electronic processor 600 may determine a fault condition for the power machine 400 (at block 910). The electronic processor 600 may determine the fault condition based on the electric current data 615 (including, e.g., the electric current trend data 620). The electronic processor 600 may determine the fault condition for one or more components of the power machine 400, such as, e.g., the collection system 505, the impeller 440, etc. As described herein, a fault condition may include (or represent) an obstruction in the discharge chute 445, an obstruction in the impeller 440 (e.g., within a housing of the impeller 440), an amount of yard waste (or material) in the collection receptacle(s) 450 of the collection system 505 being at a predetermined capacity level (e.g., when the collection receptacle(s) 450 reach a maximum fill capacity), etc.

As described herein, the electric motor 435 drives (or rotates) the impeller 440, creating a flow of air within a housing of the impeller 440 (or within the discharge chute 445). The airflow within a housing of the impeller 440 (or within the discharge chute 445) may be laminar (e.g., a generally smooth and regular flow of air). However, in some instances, the airflow within a housing of the impeller 440 may be turbulent (e.g., irregular flow of air). Turbulent airflow within the impeller 440 may occur when airflow within the discharge chute 445 is disrupted (or prevented), such as, e.g., as a result of a blockage within the discharge chute 445, where the blockage prevents the flow of air within the discharge chute 445. For instance, when air cannot move throughout the discharge chute 445, less air is moving through a housing of the impeller 440, which results in less power being provided to the electric motor 435 (since the impeller 440 moves less air). As such, the electric motor 435 may experience a reduction in electric current when airflow within a housing of the impeller 440 (or within the discharge chute 445) is turbulent, which, ultimately, may indicate a fault condition with the collection system 505 (e.g., a blockage within the discharge chute 445 or reaching a maximum capacity level of the collection receptacle(s) 450). As described in greater detail herein, in some instances, the electric motor 435 may experience an increase in electric current, which may be indicative of a fault condition (e.g., a blockage with respect to the impeller 440, where such a blockage may result in an increase in electric current).

Accordingly, the electronic processor 600 may monitor the electric current data 615 in order to detect a reduction in electric current of the electric motor 435 and, ultimately, to determine a fault condition associated with the collection system 505.

In some instances, the electronic processor 600 may determine a fault condition for the collection system 505 responsive to detecting that the electric current of the electric motor 435 is below a electric current threshold. In some configurations, the electric current threshold may be a predetermined electric current threshold. For instance, in some examples, the electric current threshold may be an electric current value (a predetermined electric current value). In some instances, the electric current threshold may be an electric current value of an expected or anticipated electric current of the electric motor 435 during operation of the power machine 400 (e.g., during normal operation of the power machine 400). For example, when the expected or anticipated electric current is 20 amps, the predetermined electric current threshold may be 20 amps. Following this example, the electronic processor 600 may determine a fault condition when the present electric current is less than 20 amps. Conversely, the electronic processor 600 may not determine a fault condition when the present electric current is greater than or equal to 20 amps. Alternatively, or in addition, in some configurations, the electric current threshold may be an electric current value established (or otherwise set) by an operator of the power machine 400.

Alternatively, in some configurations, the electric current threshold may be based on a percentage, such as, e.g., a percentage deviation from an expected or anticipated electric current of the electric motor 435 during operation of the power machine 400. In some examples, an operator of the power machine 400 may set the deviation percentage. For example, the operator may set the deviation percentage based on a sensitivity preference of the operator. The electronic processor 600 may determine a fault condition when the present electric current deviates from the expected or anticipated electric current by more than the deviation percentage. As one specific example, when the expected or anticipated electric current is 30 amps and the deviation percentage is 5%, the electronic processor 600 may determine a fault condition when the present electric current is less than 28.5 amps (e.g., expected electric current (30 amps) minus 5% of the expected electric current (30 amps)).

Accordingly, in some instances, the electric current threshold may vary relative to an expected or anticipated electric current of the electric motor 435. As such, in some configurations, the technology disclosed herein may take into consideration an application or one or more operating parameters or characteristics of the power machine 400 (or component(s) thereof) such that the electric current threshold represents or reflects the application or the one or more operating parameters or characteristics of the power machine 400 (or component(s) thereof). For example, in some instances, the technology disclosed herein may consider an operating speed of the electric motor 435, whether the power machine 400 is intended for heavier operations or lighter operations, etc. For instance, when the electric motor 435 of the power machine 400 has a higher operating speed, the electric motor 435 will similarly have a higher operating electric current (as speed is proportional to electric current for electric motors). As such, in some instances, by utilizing percentages for the electric current threshold, the higher operating speed of the electric motor 435 may be taken into consideration.

In some examples, the electronic processor 600 may establish (or otherwise set) the electric current threshold based on input from an operator of the power machine 400. For instance, the operator of the power machine 400 may set the electric current threshold. The operator of the power machine 400 may set the electric current threshold based on, e.g., a sensitivity preference of the operator. A sensitivity preference may represent how much of a deviation from an expected or anticipated electric current is acceptable or allowable to an operator of the power machine 400. For instance, when an operator sets an electric current threshold that allows for a high electric current deviation from the expected or anticipated electric current, the sensitivity associated with detecting a fault may be decreased (e.g., less sensitive). One specific example, when the expected or anticipated electric current is 20 amps during operation, an operator that prefers a more sensitive fault detection may set the electric current threshold to 19 amps. Conversely, an operator that prefers a less sensitive fault detection may set the electric current threshold to 15 amps.

In some instances, the electric current threshold may be based on an acceptable error tolerance (or variation) in an expected or anticipated electric current of the electric motor 435. For example, the electric current threshold may be established such that some variation in the expected or anticipated electric current of the electric motor 435 is allowed.

Alternatively, or in addition, in some configurations, the electronic processor 600 may determine a fault condition for the collection system 505 using an electric current range or window. The electric current range or window may be based on (or otherwise defined using) electric current values, percentages, etc. In some examples, the electric current range may be defined using one or more static electric current values as upper and lower bounds of the electric current range. As one example, the electric current range may include an upper bound of 30 amps and a lower bound of 20 amps. In some instances, the electric current range may be defined using percentages relative to an expected or anticipated electric current. For instance, the electric current range may include an upper bound that is defined as an electric current value representing a 5% increase from the expected or anticipated electric current and a lower bound that is defined as an electric current value representing a 5% decrease from the expected or anticipated electric current. As one specific example, when the expected or anticipated electric current is 20 amps and the electric current range is based on a percentage of 5%, the electric current range may include an upper bound of 21 amps (e.g., expected electric current (20 amps) plus 5% of the expected electric current (20 amps)) and a lower bound of 19 amps (e.g., expected electric current (20 amps) minus 5% of the expected electric current (20 amps)).

Accordingly, in some instances, the electric current range or window may vary relative to an expected or anticipated electric current of the electric motor 435. As such, in some instances, the technology disclosed herein may take into consideration an application or one or more operating parameters or characteristics of the power machine 400 (or component(s) thereof) (e.g., an operating speed of the electric motor 435, whether the power machine 400 is intended for heavier operations or lighter operations, etc.).

In some examples, the electric current range may be based on an electric current trend for the electric motor 435 (e.g., the electric current trend data 620). For instance, the electronic processor 600 may determine a fault condition based on whether a present electric current of the electric motor 435 is outside of (or deviates from) an electric current range that represents an electric current trend for the electric motor 435. In some configurations, the electric current range may include an upper electric current threshold value and a lower electric current threshold value. In some examples, the upper bound and the lower bound may be determined based on an acceptable tolerance or variation (e.g., an error tolerance).

In some examples, the electronic processor 600 may establish (or otherwise set) the electric current range based on input from an operator of the power machine 400. For instance, the operator of the power machine 400 may set the electric current range. The operator of the power machine 400 may set the electric current range based on, e.g., a sensitivity preference of the operator.

In such configurations, the electronic processor 600 may determine one or more fault conditions for the power machine 400 (or component(s) thereof) based on whether a present electric current of the electric motor 435 is above the electric current range, within the electric current range, or below the electric current range. As one example, the electronic processor 600 may determine that no fault condition is present for the power machine 400 (or component(s) thereof) when the present electric current is within the electric current range (e.g., the power machine 400 is operating as expected). As another example, the electronic processor 600 may determine that a first fault condition is present for the power machine 400 (or component(s) thereof) when the present electric current is below the electric current range. As yet another example, the electronic processor 600 may determine that a second fault condition is present for the power machine 400 (or component(s) thereof) when the present electric current is above the electric current range. In some instances, the electronic processor 600 may determine different fault conditions based on whether the present electric current is above or below the electric current range. For example, when the present electric current is above the electric current range, the electronic processor 600 may determine a first fault condition and, when the present electric current is below the electric current range, the electronic processor 600 may determine a second fault condition different from the first fault condition. As one specific example, when the electronic processor 600 determines that the present electric current is below the electric current range, the electronic processor 600 may determine that there is a blockage in the discharge chute 445 (e.g., as a fault condition) and, when the electronic processor 600 determines that the present electric current is above the electric current range, the electronic processor 600 may determine that there is a fault with another component of the power machine 400. As described herein, in some instances, a blockage with respect to the impeller 440 (e.g., a blockage in a housing of the impeller 440), a cutting assembly (e.g., a rock or other obstruction stuck in a blade of the mower deck), or the like may result in an increase in electric current. As such, in some instances, when the present electric current is above a current threshold or electric current range, the electronic processor 600 may determine that the fault condition is a blockage with respect to the impeller 440.

In some configurations, the electric current threshold or electric current range may represent (or otherwise be associated with) electric current values indicative of a future fault condition. A future fault condition may include a fault condition that is imminent or likely to occur based on current operating conditions (e.g., present electric current of the electric motor 435). Accordingly, in such configurations, the electronic processor 600 may predict a fault condition (e.g., a future or imminent fault condition) for the power machine 400 (or component(s) thereof). As one example, the electronic processor 600 may predict the fault condition when a first deviation in electric current is detected (e.g., based on the electric current data 615) while the electronic processor 600 may determine that the fault condition has occurred when a second deviation in electric current is detected, where the first deviation is smaller than the second deviation.

In some instances, the first deviation may correspond to a first range of electric current values relative to an expected or anticipated electric current and the second deviation may correspond to a second range of electric current values relative to the expected or anticipated electric current. In some examples, the first range of electric current values and the second range electric current values do not overlap (e.g., do not repeat or otherwise include the same electric current value). Alternatively, in some examples, the first range of the electric current values and the second range of electric current values at least partially overlap (e.g., at least one electric current value included in the first range of electric current values is repeated or otherwise included in the second range of electric current values). As one example, an operation may involve an electric current of 30 amps with a first electric current drop to 20 amps and a second, subsequent electric current drop to 15 amps. The first electric current drop may suggest a potential clog (e.g., as a predicted future fault condition). The second, subsequent electric current drop may confirm the clog (e.g., as an actual, presently occurring fault condition).

As illustrated in FIG. 9, the electronic processor 600 may control the power machine 400 based on the fault condition (at block 915). In some examples, the electronic processor 600 may control one or more components of the power machine 400. The electronic processor 600 may control the component(s) of the power machine 400 by altering an operating parameter (e.g., an electric current provided to the component(s)). In some instances, the electronic processor 600 may control the power machine 400 differently based on a particular type of fault condition (e.g., a first fault condition detected responsive to an electric current below a threshold or range or a second fault condition detected responsive to an electric current above a threshold or range), a severity of the fault condition (e.g., a predicted occurrence of a fault condition or an actual occurrence of a fault condition), etc.

In some examples, the electronic processor 600 may control the tractive system 425 (or component(s) thereof) responsive to the fault condition. For instance, in some configurations, the electronic processor 600 may control one or more of the tractive actuators 465A, 465B such that a travel speed of the power machine 400 is reduced. Alternatively, the electronic processor 600 may control one or more of the tractive actuators 465A, 465B such that a travel of the power machine 400 is prevented. Alternatively, or in addition, in some configurations, the electronic processor 600 may control one or more work element(s) 410 (or component(s) thereof) responsive to the fault condition. In some examples, the electronic processor 600 may alter a rotation speed of one or more cutting blades of a mower deck such that the rotation speed is reduced or stopped.

Alternatively, or in addition, in some examples, the electronic processor 600 may control the human-machine interface 432 (or component(s) thereof) responsive to the fault condition. For example, the electronic processor 600 may generate and provide an alert indicating the fault condition to an operator of the power machine 400. The electronic processor 600 may control the human-machine interface 432 to provide the alert. In some examples, the electronic processor 600 may control a display device of the human-machine interface 432 to display the alert to an operator of the power machine. In such examples, the alert may be displayed as a symbol (e.g., a symbol specific to the fault condition), text (e.g., text specifying the fault condition), etc. As another example, the electronic processor 600 may control an indicator light of the human-machine interface 432 to indicate the fault condition. In some instances, the electronic processor 600 may control an indicator light specific to a type of fault such that when that indicator light is illuminated a particular fault condition is indicated. The electronic processor 600 may control the indicator light to illuminate in various patterns, durations, colors, etc. For example, a first color of the indicator light may represent a first fault condition while a second color of the indicator light may represent a second fault condition. As another example, a first illumination pattern may represent a first fault condition while a second illumination pattern may represent a second fault condition.

Alternatively, or in addition, in some examples, the electronic processor 600 may control the power machine 400 such that an alert is transmitted to a user device external to the power machine 400 (e.g., a mobile communication device, a portable computing device, etc.). In such examples, the electronic processor 600 may generate an alert and transmit the alert via the communication system 420, such that the alert is transmitted to a user device external to the power machine 400.

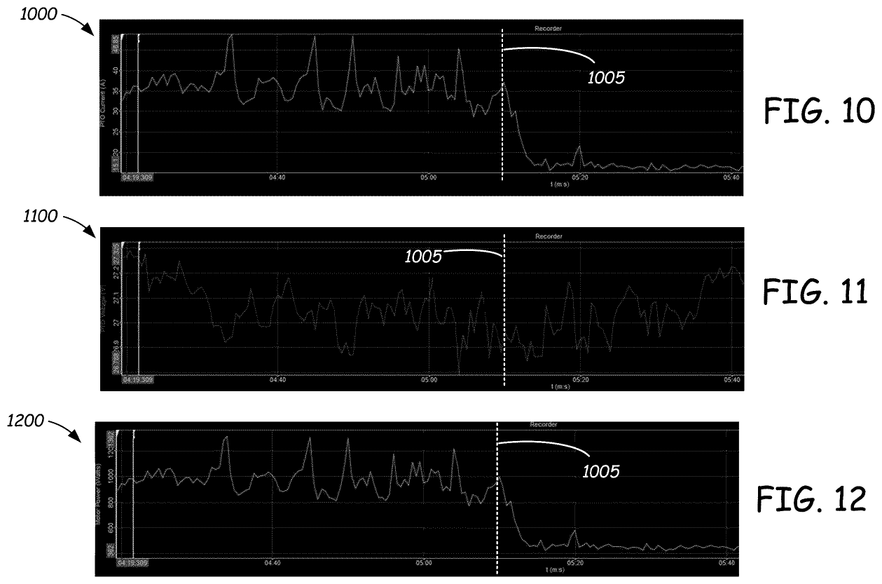

FIG. 10-12 are graphs illustrating various characteristics of the electric motor 435 during a fault condition, where the fault condition is a blockage in the discharge chute 445. FIG. 10 is a graph 1000 illustrating electric current data of the electric motor 435 during the fault condition. FIG. 11 is a graph 1100 illustrating voltage data of the electric motor 435 during the fault condition. FIG. 12 is a graph 1200 illustrating power data of the electric motor 435 during the fault condition. As illustrated in the graphs 1000, 1100, 1200 of FIGS. 10-12, a sudden drop off (represented by a dotted line labeled with reference numeral 1005) is experienced from 35 A to 18 A at approximately 5 minutes and 10 seconds. Additionally, as illustrated in FIGS. 10-12, the respective data also shows that the electric current starts to drop (or reduce) even before the blockage is fully formed. Such data may be used to determine (or predict) that the discharge chute 445 is “going to clog” and may be used for an automated slow-down of the speed of the power machine 400.

As used herein, unless otherwise limited or defined, “or” indicates a non-exclusive list of components or operations that can be present in any variety of combinations, rather than an exclusive list of components that can be present only as alternatives to each other. For example, a list of “A, B, or C” indicates options of: A; B; C; A and B; A and C; B and C; and A, B, and C. Correspondingly, the term “or” as used herein is intended to indicate exclusive alternatives only when preceded by terms of exclusivity, such as “either,” “one of,” “only one of,” or “exactly one of. ” For example, a list of “one of A, B, or C” indicates options of: A, but not B and C; B, but not A and C; and C, but not A and B. A list preceded by “one or more” (and variations thereon) and including “or” to separate listed elements indicates options of one or more of any or all of the listed elements. For example, the phrases “one or more of A, B, or C” and “at least one of A, B, or C” indicate options of: one or more A; one or more B; one or more C; one or more A and one or more B; one or more B and one or more C; one or more A and one or more C; and one or more of A, one or more of B, and one or more of C. Similarly, a list preceded by “a plurality of” (and variations thereon) and including “or” to separate listed elements indicates options of multiple instances of any or all of the listed elements. For example, the phrases “a plurality of A, B, or C” and “two or more of A, B, or C” indicate options of: A and B; B and C; A and C; and A, B, and C.

Also as used herein, unless otherwise expressly limited or defined, the term “automatic operations” refers to operations that are at least partly dependent on electronic application of computer algorithms for decision-making without human intervention. In this regard, unless otherwise expressly limited or defined, “automatic travel” refers to travel of a power machine or other vehicle in which at least some decisions regarding steering, speed, distance, or other travel parameters are made without direct intervention by a human operator. Relatedly, the term “automated operations” (and the like), unless otherwise expressly limited or defined, refers to a subset of automatic operations for which no intervention by a human operator is required. For example, automated travel can refer to automatic travel of a power machine or other vehicle during which steering, speed, distance, or other travel parameters are determined in real time without operator input. In this regard, however, operator input may sometimes be received to start, stop, interrupt, or define parameters (e.g., top speed) for automated travel or other automated operations.

In some embodiments, aspects of the invention, including computerized implementations of methods according to the invention, can be implemented as a system, method, apparatus, or article of manufacture using standard programming or engineering techniques to produce software, firmware, hardware, or any combination thereof to control a processor device (e.g., a serial or parallel general purpose or specialized processor chip, a single- or multi-core chip, a microprocessor, a field programmable gate array, any variety of combinations of a control unit, arithmetic logic unit, and processor register, and so on), a computer (e.g., a processor device operatively coupled to a memory), or another electronically operated controller to implement aspects detailed herein. Accordingly, for example, embodiments of the invention can be implemented as a set of instructions, tangibly embodied on a non-transitory computer-readable media, such that a processor device can implement the instructions based upon reading the instructions from the computer-readable media. Some embodiments of the invention can include (or utilize) a control device such as an automation device, a special purpose or general purpose computer including various computer hardware, software, firmware, and so on, consistent with the discussion below. As specific examples, a control device can include a processor, a microcontroller, a field-programmable gate array, a programmable logic controller, logic gates etc., and other typical components that are known in the art for implementation of appropriate functionality (e.g., memory, communication systems, power sources, user interfaces and other inputs, etc.). In some embodiments, a control device can include a centralized hub controller that receives, processes and (re)transmits control signals and other data to and from other distributed control devices (e.g., an engine controller, an implement controller, a drive controller, etc.), including as part of a hub-and-spoke architecture or otherwise.

The term “article of manufacture” as used herein is intended to encompass a computer program accessible from any computer-readable device, carrier (e.g., non-transitory signals), or media (e.g., non-transitory media). For example, computer-readable media can include but are not limited to magnetic storage devices (e.g., hard disk, floppy disk, magnetic strips, and so on), optical disks (e.g., compact disk (CD), digital versatile disk (DVD), and so on), smart cards, and flash memory devices (e.g., card, stick, and so on). Additionally it should be appreciated that a carrier wave can be employed to carry computer-readable electronic data such as those used in transmitting and receiving electronic mail or in accessing a network such as the Internet or a local area network (LAN). Those skilled in the art will recognize that many modifications may be made to these configurations without departing from the scope or spirit of the claimed subject matter.

Certain operations of methods according to the invention, or of systems executing those methods, may be represented schematically in the FIGS. or otherwise discussed herein. Unless otherwise specified or limited, representation in the FIGS. of particular operations in particular spatial order may not necessarily require those operations to be executed in a particular sequence corresponding to the particular spatial order. Correspondingly, certain operations represented in the FIGS., or otherwise disclosed herein, can be executed in different orders than are expressly illustrated or described, as appropriate for particular embodiments of the invention. Further, in some embodiments, certain operations can be executed in parallel, including by dedicated parallel processing devices, or separate computing devices configured to interoperate as part of a large system.

As used herein in the context of computer implementation, unless otherwise specified or limited, the terms “component,” “system,” “module,” “block,” and the like are intended to encompass part or all of computer-related systems that include hardware, software, a combination of hardware and software, or software in execution. For example, a component may be, but is not limited to being, a processor device, a process being executed (or executable) by a processor device, an object, an executable, a thread of execution, a computer program, or a computer. By way of illustration, both an application running on a computer and the computer can be a component. One or more components (or system, module, and so on) may reside within a process or thread of execution, may be localized on one computer, may be distributed between two or more computers or other processor devices, or may be included within another component (or system, module, and so on).

In some implementations, devices or systems disclosed herein can be utilized, manufactured, installed, etc. using methods embodying aspects of the invention. Correspondingly, any description herein of particular features, capabilities, or intended purposes of a device or system is generally intended to include disclosure of a method of using such devices for the intended purposes, of a method of otherwise implementing such capabilities, of a method of manufacturing relevant components of such a device or system (or the device or system as a whole), and of a method of installing disclosed (or otherwise known) components to support such purposes or capabilities. Similarly, unless otherwise indicated or limited, discussion herein of any method of manufacturing or using for a particular device or system, including installing the device or system, is intended to inherently include disclosure, as embodiments of the invention, of the utilized features and implemented capabilities of such device or system.

Although the present invention has been described with reference to preferred embodiments, workers skilled in the art will recognize that changes may be made in form and detail to the disclosed embodiments without departing from the spirit and scope of the concepts discussed herein.

What is claimed is:

1. A method of controlling a power machine, the method comprising:
monitoring, with an electronic processor, electric current for an electric motor of a collection system of the power machine;
determining, with the electronic processor, a fault condition for the collection system responsive to detecting that the electric current is below a predetermined electric current threshold; and
controlling, with the electronic processor, the power machine based on the fault condition.

2. The method of claim 1, wherein controlling, with the electronic processor, the power machine based on the fault condition includes generating and providing, with the electronic processor, an alert indicating the fault condition to an operator of the power machine.

3. The method of claim 2, wherein generating and providing, with the electronic processor, the alert includes controlling, with the electronic processor, a human-machine interface of the power machine to indicate the fault condition.

4. The method of claim 3, wherein controlling, with the electronic processor, the human-machine interface includes controlling at least one of an indicator light or a display device.

5. The method of claim 2, wherein generating and providing, with the electronic processor, the alert includes transmitting the alert to a user device external to the power machine.

6. The method of claim 1, wherein controlling, with the electronic processor, the power machine based on the fault condition includes controlling an electric actuator for a tractive element of the power machine such that a travel speed of the power machine is reduced.

7. The method of claim 1, wherein determining, with the electronic processor, the fault condition for the collection system includes determining, with the electronic processor, that a discharge chute of the collection system is blocked.

8. The method of claim 1, wherein determining, with the electronic processor, the fault condition for the collection system includes determining, with the electronic processor, that a collection receptacle of the collection system is at a predetermined capacity level.

9. The method of claim 1, wherein determining, with the electronic processor, the fault condition for the collection system of the power machine includes predicting, with the electronic processor, the fault condition for the collection system of the power machine.

10. The method of claim 1, wherein monitoring, with the electronic processor, the electric current of the electric motor includes monitoring, with the electronic processor, the electric current of an electric motor attached to a discharge chute of the collection system, wherein the electric motor is configured to control an airflow within the discharge chute of the collection system.

11. A system of controlling a power machine, the system comprising:
one or more electronic processors configured to:
monitor an electric current trend for an electric motor of a collection system of the power machine;
detect a deviation of a present electric current of the electric motor from the electric current trend;
when the deviation of the present electric current is a reduced electric current value relative to the electric current trend, determine a first fault condition for the collection system of the power machine;
when the deviation of the present electric current is an increased electric current value relative to the electric current trend, determine a second fault condition for the power machine; and
control the power machine based on the first or second fault condition.

12. The system of claim 11, wherein the deviation occurs when an electric current value of the present electric current falls below an average electric current value of the electric current trend by a predetermined amount.

13. The system of claim 11, wherein the electric motor of the collection system includes an electric motor coupled to a discharge chute of the collection system, wherein the electric motor is also coupled to an impeller and configured to drive the impeller such that movement of the impeller causes a flow of air within the discharge chute of the collection system.

14. The system of claim 11, wherein the one or more electronic processors are configured to control the power machine based on the fault condition by at least one of:
generating and transmitting an alert indicating the fault condition to an operator of the power machine; or
controlling an electric actuator for a tractive element of the power machine such that a travel speed of the power machine is reduced.

15. A mower comprising:
a frame;
a power source;
a cutting assembly coupled to the frame and configured to be powered by the power source for cutting operations;
one or more drive motors coupled to the frame and configured to be powered by the power source to move the mower over terrain during cutting operations;
a collection system coupled to the cutting assembly, the collection system including:
a discharge chute coupled to the cutting assembly; and
an electric motor coupled to an impeller and configured to drive the impeller to control airflow within the discharge chute; and
an electronic controller in communication with the one or more drive motors and the electric motor, the electronic controller configured to:
monitor an electric current trend for the electric motor;
detect a deviation of a present electric current of the electric motor from the electric current trend, wherein the deviation of the present electric current is a reduced electric current value relative to the electric current trend;
determine, based on the deviation, a fault condition for the collection system; and
control the mower based on the fault condition.

16. The system of claim 15, wherein the deviation occurs when an electric current value of the present electric current is below an electric current range of the electric current trend.

17. The system of claim 15, wherein the electronic controller is configured to:
determine, as the fault condition, a first fault condition when an electric current value of the present electric current is below an electric current range of the electric current trend; and
determine, as the fault condition, a second fault condition when the electric current value of the present electric current is above the electric current range of the electric current trend.

18. The system of claim 15, wherein the fault condition represents at least one of:
an obstruction in the discharge chute; or
an amount of material in a collection receptacle of the collection system being at a predetermined capacity level.

19. The system of claim 15, wherein the electric current trend represents an average electric current value for a series of historical electric current values for the electric motor.
